(19) United States
(12) Patent Application Publication
(10) Pub. No.: US 2024/0387334 A1
(43) Pub. Date: Nov. 21, 2024

(54) SEMICONDUCTOR MODULE AND HEAT DISSIPATION BASE

(71) Applicant: FUJI ELECTRIC CO., LTD., Kawasaki-shi (JP)

(72) Inventor: Makoto ISOZAKI, Kawasaki-shi (JP)

(73) Assignee: FUJI ELECTRIC CO., LTD., Kawasaki-shi (JP)

(21) Appl. No.: 18/589,737

(22) Filed: Feb. 28, 2024

(30) Foreign Application Priority Data
May 15, 2023 (JP) 2023-079966

(51) Int. Cl. H01L 23/495; H01L 23/00; H01L 23/367; H01L 25/065

(52) U.S. Cl. CPC H01L 23/49568; H01L 23/3672; H01L 23/49531; H01L 24/08; H01L 24/48; H01L 25/0652; H01L 2224/08145; H01L 2224/08175; H01L 2224/48137; H01L 2224/48177; H01L 2924/01013; H01L 2924/01029; H01L 2924/13055; H01L 2924/13091

(57) ABSTRACT

A semiconductor module includes a semiconductor element, a wiring board on which the semiconductor element is mounted, and a heat dissipation base including a first surface having a first region in which the wiring board is bonded and a second surface opposite to the first surface. The heat dissipation base is warped to be convexed in a direction from the first surface toward the second surface. The heat dissipation base has a plurality of fastening holes respectively provided at respective ones of a plurality of corner portions of the heat dissipation base, and a plurality of recesses provided in the first surface in respective ones of a plurality of peripheral areas. The plurality of peripheral areas are respectively located in a second region excluding the first region, at a peripheral edge of the first surface around respective ones of the plurality of fastening holes.

### CROSS-REFERENCE TO RELATED APPLICATION

This application is based upon and claims the benefit of priority to Japanese Patent Application No. 2023-079966, Filed on May 15, 2023, the entire contents of which are incorporated herein by reference.

### BACKGROUND OF THE INVENTION

### 1. Technical Field

The present invention relates to a semiconductor module including a semiconductor element, a wiring board, and a heat dissipation base and a heat dissipation base to which the wiring board is bonded.

### 2. Description of the Related Art

There is a semiconductor device used for a power conversion device such as an inverter device in which a heat dissipation base in which a wiring board, a semiconductor element, and the like are arranged is attached to a cooler (for example, refer to JP 2006-165279 A, JP 2018-195717 A, JP 2017-017280 A, JP 2007-012928 A, JP H06-169037 A, JP 2006-303375 A, U.S. Pat. No. 7,511,961 B, and JP 2020-017702 A). As a heat dissipation base used for this type of semiconductor device, there is a heat dissipation base in which a second surface that faces the cooler and is on an opposite side of a first surface on which the wiring board, the semiconductor element, and the like are arranged is molded to have a convex shape.

A wiring board is bonded to a first surface of a heat dissipation base with a bonding material. When the heat dissipation base molded to have a convex second surface is attached to a cooler, the second surface deforms in a direction in which the convex curved surface changes to a flat surface. Therefore, by deforming the heat dissipation base, a deformed stress equal to or more than a deflective strength is applied to the wiring board bonded to the first surface of the heat dissipation base, and there is a case where the wiring board is damaged.

In one aspect, an object of the present invention is to prevent a damage of a wiring board caused by deformation of a heat dissipation base at the time of fastening.

### SUMMARY OF THE INVENTION

A semiconductor module according to one aspect includes a semiconductor element, a wiring board on which the semiconductor element is mounted, and a heat dissipation base including a first surface to which the wiring board is bonded and a second surface positioned on an opposite side of the first surface, in which the heat dissipation base is warped so that the second surface is a convex curved surface, fastening holes are provided at a plurality of corner portions of the first surface of the heat dissipation base, and the heat dissipation base has a recess positioned around the fastening hole and across a peripheral edge of the first surface, in a second region excluding a first region, to which the wiring board is bonded, in the first surface.

According to the above aspect, it is possible to prevent a damage of a wiring board caused by deformation at the time of fastening a heat dissipation base.

### BRIEF DESCRIPTION OF THE DRAWINGS

FIG. 1 is a top view illustrating a configuration example of an energy conversion device according to an embodiment;

FIG. 2 is a cross-sectional side view illustrating a configuration example of inside of the energy conversion device taken along an A-A′ line in FIG. 1;

FIG. 3 is a cross-sectional side view of the energy conversion device taken along a B-B′ line in FIG. 1;

FIG. 4 is a diagram illustrating a configuration example of a circuit of a semiconductor module;

FIG. 5 is a bottom view for explaining an example of a coating pattern of a heat conductive material when a heat dissipation base is attached to a cooler;

FIG. 6 is a diagram for explaining a state of spread of the heat conductive material when the heat dissipation base is attached to the cooler;

FIG. 7 is a diagram for explaining an example of a problem that occurs when the heat dissipation base is attached to the cooler;

FIGS. 8A to 8C are a top view of a first configuration example of the heat dissipation base according to the embodiment and a side view illustrating an example of a cross-sectional shape of two grooves;

FIG. 9 is a top view illustrating a second configuration example of the heat dissipation base according to the embodiment;

FIGS. 10A and 10B are a top view illustrating a third configuration example of the heat dissipation base according to the embodiment and a diagram for explaining a length of the groove;

FIGS. 11A to 11C are a top view and a side view illustrating a fourth configuration example of the heat dissipation base according to the embodiment and a diagram for explaining a length of a cut-away part; and

FIG. 12 is a diagram for explaining a difference in tensile stress to be applied to a wiring board between the embodiment and a comparative example.

### DETAILED DESCRIPTION

Hereinafter, an embodiment of the present invention will be described in detail with reference to the drawings. Note that each of X, Y, and Z axes in each drawing to be referred is indicated to define a plane or a direction in an energy conversion device, a semiconductor module, or the like to be illustrated. The X, Y, and Z axes are orthogonal to each other and form a right-handed system. In the following description, the Z direction may be referred to as a vertical direction. Furthermore, a plane including the X axis and the Y axis may be referred to as an XY plane, a plane including the Y axis and the Z axis may be referred to as a YZ plane, and a plane including the Z axis and the X axis may be referred to as a ZX plane. Such directions and planes are terms used for convenience of description. Thus, depending of a posture of attachment of the energy conversion device or the like, a correspondence relationship with the X, Y, and Z directions may vary. For example, here, a surface facing a Z direction front side (+Z direction) in a member forming the energy conversion device is referred to as a top surface, and a surface facing a Z direction negative side (−Z direction) is referred to as a bottom surface. However, the surface facing the Z direction negative side may be referred to as the top surface, and the surface facing the Z direction front side may be referred to as the bottom surface. Furthermore, here, the term “in plan view” means a case where a top surface or a bottom surface (XY plane) of the energy conversion device or the like is viewed from the Z direction.

An aspect ratio and a size relationship between the members in each drawing are merely schematically represented, and do not necessarily coincide with a relationship in the energy conversion device or the like actually manufactured. For convenience of description, it is also assumed that the size relationship between the members may be exaggerated. Furthermore, in different drawings, shapes of the same member may be different.

In the following description, as an example of an energy conversion device including a semiconductor module according to the present embodiment, a device is exemplified that is applied to a power conversion device such as an industrial or an in-vehicle motor inverter device. Thus, in the following description, detailed description of the same or similar configuration, function, operation, assembly method, or the like as those of a known energy conversion device will be omitted.

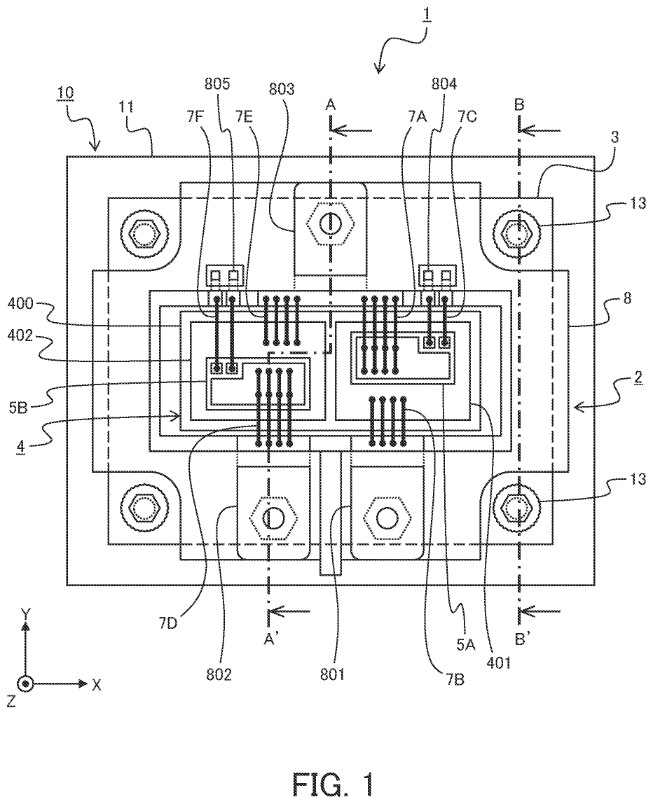

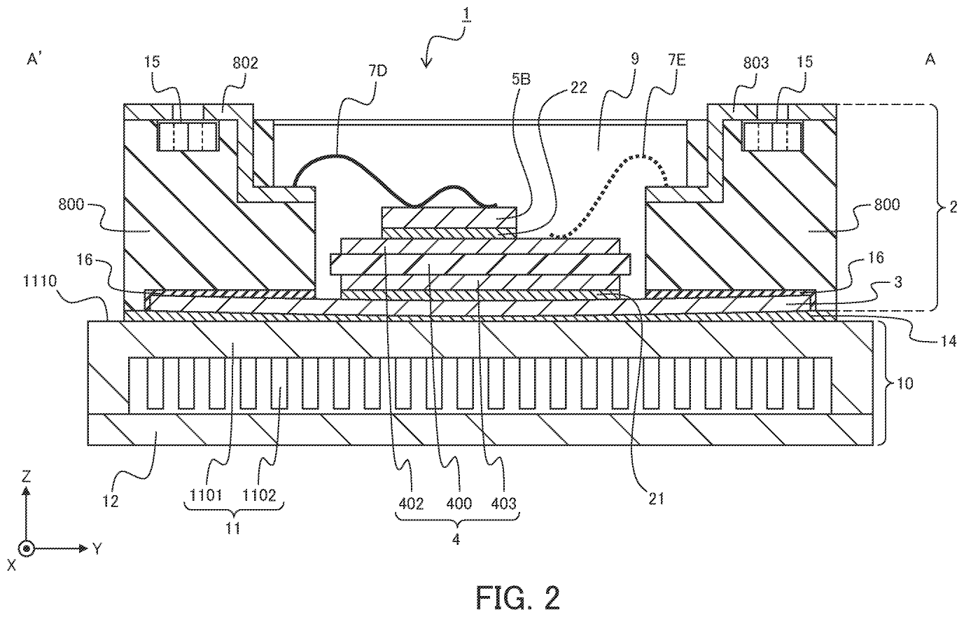

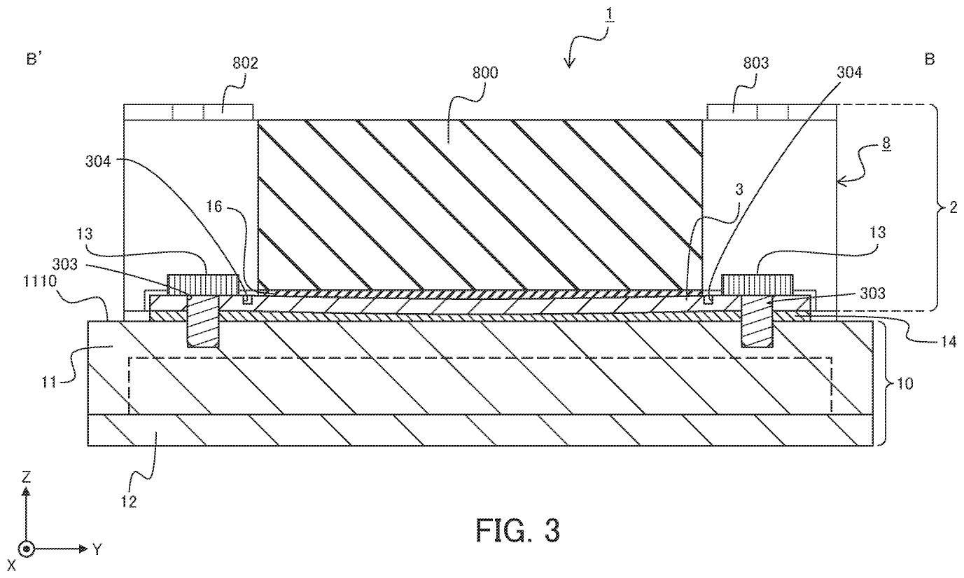

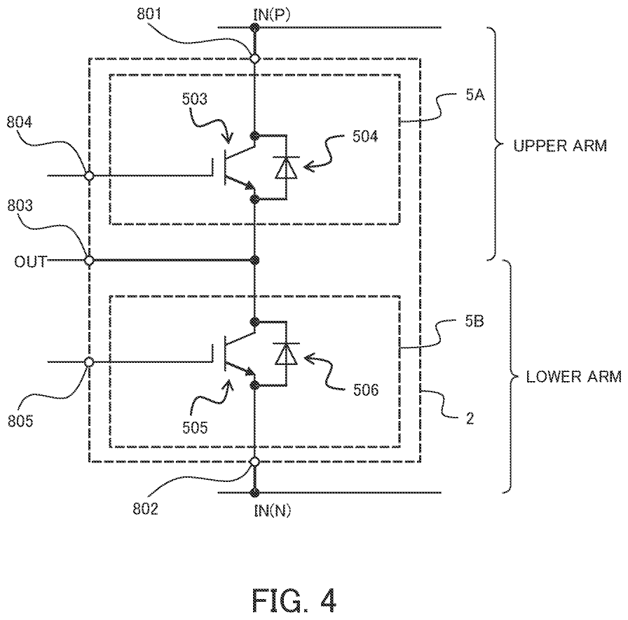

FIG. 1 is a top view illustrating a configuration example of an energy conversion device 1 according to the embodiment. FIG. 2 is a cross-sectional side view illustrating a configuration example of inside of the energy conversion device 1 taken along an A-A′ line in FIG. 1. FIG. 3 is a cross-sectional side view of the energy conversion device 1 taken along a B-B′ line in FIG. 1. FIG. 4 is a diagram illustrating a configuration example of a circuit of a semiconductor module 2. Note that, in FIG. 1, a sealing material 9 that seals a wiring board 4, semiconductor elements 5A and 5B, or the like is omitted. In FIG. 2, a configuration example is schematically illustrated in a case where a portion of the energy conversion device 1 taken along the A-A′ line in FIG. 1 on the left side of the A-A′ line as a boundary is viewed from a right side. In FIG. 2, hatching indicating a cross section of the sealing material 9 is omitted. In FIG. 3, a configuration example is schematically illustrated in a case where a portion of the energy conversion device 1 taken along the B-B′ line in FIG. 1 on the left side of the B-B′ line as a boundary is viewed from a right side.

The energy conversion device 1 illustrated in FIGS. 1 to 3 includes the semiconductor module 2 as a semiconductor device and a cooler 10. The semiconductor module 2 includes a heat dissipation base 3, the wiring board 4, the semiconductor elements 5A and 5B, a plurality of bonding wires 7A to 7F, a case 8, and the sealing material 9. The cooler 10 includes a fin 11 and a water jacket 12. The semiconductor module 2 is inserted into a fastening hole of the heat dissipation base 3, and is attached to the cooler 10 with a screw 13 having a male screw to be screwed into a screw hole (female screw) provided in a top surface 1110 of the fin 11 of the cooler 10. The heat dissipation base 3 of the semiconductor module 2 and the fin 11 of the cooler 10 are connected via a heat conductive material 14 such as thermal grease or thermal compound.

The semiconductor module 2 illustrated in FIGS. 1 to 3 forms a single-phase voltage type half-bridge inverter circuit as illustrated in FIG. 4. On the top surface of the heat dissipation base 3 of this type of semiconductor module 2, the wiring board 4 is arranged. The wiring board 4 includes an insulating substrate 400, a first conductor pattern 401 and a second conductor pattern 402 provided on a top surface (example of first surface) of the insulating substrate 400, and a third conductor pattern 403 provided on a bottom surface (example of second surface) of the insulating substrate 400. The wiring board 4 may be, for example, a direct copper bonding (DCB) substrate or an active metal brazing (AMB) substrate. The wiring board 4 may be referred to as a laminated substrate or an insulating circuit substrate.

The insulating substrate 400 is not limited to a specific substrate. The insulating substrate 400 may be, for example, a ceramic substrate including a ceramic material such as aluminum oxide (Al₂O₃), aluminum nitride (AlN), silicon nitride (Si₃N₄), or a composite material of aluminum oxide (Al₂O₃) and zirconium oxide (ZrO₂). The insulating substrate 400 may be, for example, a substrate obtained by molding an insulating resin such as epoxy resin, a substrate obtained by impregnating a base material such as a glass fiber with an insulating resin, a substrate obtained by coating a surface of a flat plate-shaped metal core with an insulating resin, or the like.

The third conductor pattern 403 is a member that functions as a heat conducting member for conducting heat generated in an inverter circuit to the heat dissipation base 3 and is formed of, for example, a metal plate, a metal foil, or the like of copper, aluminum, or the like. The third conductor pattern 403 is bonded to the heat dissipation base 3 with a bonding material 21 such as solder. The third conductor pattern 403 may be also referred to as a heat dissipation layer, a heat dissipation plate, a heat dissipation pattern, or the like.

The first conductor pattern 401 and the second conductor pattern 402 are members that function as a wiring member in the inverter circuit and are formed of, for example, a metal plate, a metal foil, or the like of copper, aluminum, or the like. The first conductor pattern 401 and the second conductor pattern 402 may be also referred to as a conductor layer, a conductor plate, a conductive layer, a wiring pattern, or the like.

On the first conductor pattern 401, the first semiconductor element 5A bonded to the first conductor pattern 401 with a bonding material (not illustrated) is arranged. On the second conductor pattern 402, the second semiconductor element 5B bonded to the second conductor pattern 402 with a bonding material 22 is arranged. The respective first semiconductor element 5A and second semiconductor element 5B are bonded to the first conductor pattern 401 and the second conductor pattern 402 with the conductive bonding material such as solder.

Each of the first semiconductor element 5A and the second semiconductor element 5B is formed of, for example, a reverse conducting (RC)-insulated gate bipolar transistor (IGBT) element obtained by integrating an IGBT element that is a switching element and a diode element such as a free wheeling diode (FWD) element or the like connected to the switching element in an inverse parallel manner. The switching element and the diode element in the semiconductor elements 5A and 5B are not limited to be formed on a Si substrate, and may be formed on a semiconductor substrate using a wide band gap semiconductor such as silicon carbide (SiC) or gallium nitride (GaN), for example. In each of this type of semiconductor elements 5A and 5B, a first main electrode (not illustrated) is provided on a bottom surface, and a second main electrode and a control electrode (gate electrode) (not illustrated) are provided on a top surface. That is, the first conductor pattern 401 is electrically connected to the first main electrode of the first semiconductor element 5A with a conductive bonding material, and the second conductor pattern 402 is electrically connected to the first main electrode of the second semiconductor element 5B with the conductive bonding material 22.

The second main electrode provided on the top surface of the first semiconductor element 5A is electrically connected to an output terminal 803 provided on the case 8 with the bonding wire 7A. The control electrode provided on the top surface of the first semiconductor element 5A is electrically connected to a first control terminal 804 provided on the case 8 with the bonding wire 7C. The first conductor pattern 401 electrically connected to the first main electrode provided on the bottom surface of the first semiconductor element 5A is electrically connected to a first input terminal (P terminal) 801 provided on the case 8 with the bonding wire 7B. That is, the first main electrode of the first semiconductor element 5A is electrically connected to the first input terminal 801 provided on the case 8, via the bonding material, the first conductor pattern 401, and the bonding wire 7B.

The second main electrode provided on the top surface of the second semiconductor element 5B is electrically connected to a second input terminal (N terminal) 802 provided on the case 8 with the bonding wire 7D. The control electrode provided on the top surface of the second semiconductor element 5B is electrically connected to a second control terminal 805 provided on the case 8 with the bonding wire 7F. The second conductor pattern 402 electrically connected to the first main electrode provided on the bottom surface of the second semiconductor element 5B is electrically connected to the output terminal 803 provided on the case 8 with the bonding wire 7E. That is, the first main electrode of the second semiconductor element 5B is electrically connected to the output terminal 803 provided on the case 8, via the bonding material 22, the second conductor pattern 402, and the bonding wire 7E.

The first input terminal 801, the second input terminal 802, the output terminal 803, the first control terminal 804, and the second control terminal 805 are integrally provided with an insulating member 800 of the case 8. The insulating member 800 has a top surface and a bottom surface opened, and has a hollow portion that can accommodate the wiring board 4, the semiconductor elements 5A and 5B, the bonding wires 7A to 7F, or the like arranged on the top surface of the heat dissipation base 3. The insulating member 800 is formed, for example, using an insulating resin material such as poly phenylene sulfide (PPS) or poly amide (PA). The first input terminal 801, the second input terminal 802, the output terminal 803, the first control terminal 804, and the second control terminal 805 are formed, for example, using a metal plate such as a copper plate and are integrated with the insulating member 800 through insert molding, for example.

A portion of the first input terminal 801, the second input terminal 802, and the output terminal 803 protruding from the top surface of the insulating member 800 is bent to extend along the top surface of the insulating member 800. An accommodation portion (not illustrated) that can accommodate a nut 15 in a direction in which an axial direction of a screw hole is set to be the vertical direction is provided in each of a region overlapping the first input terminal 801, a region overlapping the second input terminal 802, and a region overlapping the output terminal 803, in the top surface of the insulating member 800. In each of the first input terminal 801, the second input terminal 802, and the output terminal 803, a through-hole (not illustrated) that enables to screw a screw component such as a bolt into the nut 15 accommodated in the accommodation portion of the insulating member 800 is provided.

One end of each of the first input terminal 801, the second input terminal 802, the output terminal 803, the first control terminal 804, and the second control terminal 805 is exposed on an inner peripheral surface that defines the hollow portion in the insulating member 800. One ends of the bonding wires 7A to 7F are electrically connected to the portion of the corresponding terminal exposed on the inner peripheral surface of the insulating member 800.

The case 8 is attached to the heat dissipation base 3 by adhering the bottom surface of the insulating member 800 to the top surface of the heat dissipation base 3. An adhesive 16 that adheres the insulating member 800 and the heat dissipation base 3 may be an epoxy-based or silicone-based adhesive, for example. The wiring board 4, the semiconductor elements 5A and 5B, and the bonding wires 7A to 7F arranged on the top surface of the heat dissipation base 3 are positioned in a recessed space defined by the heat dissipation base 3 and the insulating member 800 of the case 8, and are sealed with the sealing material 9 filled in the recessed space. The sealing material 9 may be an epoxy resin, silicone gel, or the like, for example.

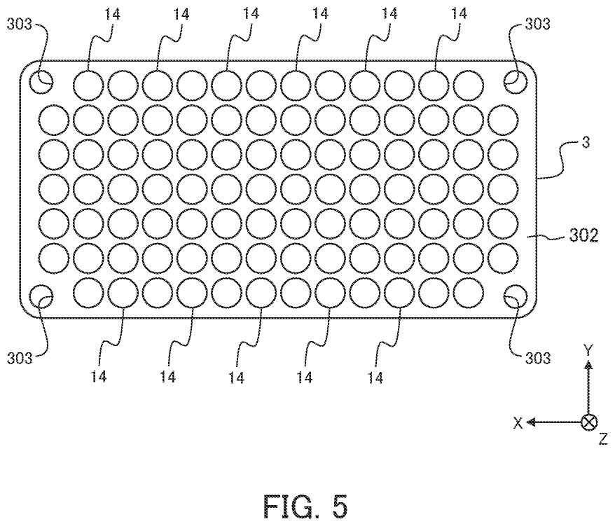

As illustrated in FIG. 1, a shape of the heat dissipation base 3 in plan view is a rectangular shape, and the heat dissipation base 3 is a plate-like member in which a fastening hole 303 (refer to FIG. 3) to be described later, in which a shaft of the screw 13 can be inserted, and a groove 304 (refer to FIG. 3) to be described later, positioned around the fastening hole 303 are formed at a corner portion. As illustrated in FIG. 5, it is preferable that R chamfering may be performed on the corner portion of the heat dissipation base 3 in plan view. Alternatively, the corner portion of the heat dissipation base 3 may be subjected to other chamfering such as C chamfering.

The heat dissipation base 3 is a member that functions as a heat conducting member that conducts heat generated by the semiconductor elements 5A and 5B to the cooler 10, and is formed of a metal plate such as a copper plate or an aluminum plate, for example. For example, an entire bottom surface 302 of the heat dissipation base 3 is warped to be a convex curved surface by warping a flat plate-shaped metal plate through press working or the like. A corner portion on an outer peripheral side of the insulating member 800 of the case 8 is cut so as not to overlap the fastening hole of the heat dissipation base 3 in plan view (more specifically, screw 13 can be screwed into screw hole of fin 11).

As described above, the semiconductor module 2 described above with reference to FIGS. 1 to 3 forms the single-phase voltage type half-bridge inverter circuit (hereinafter, described as “half-bridge inverter circuit”) as illustrated in FIG. 4. The half-bridge inverter circuit includes a switching element 503 and a diode element 504 connected between a first input end IN (P) and an output end OUT and a switching element 505 and a diode element 506 connected between a second input end IN (N) and the output end OUT. Between the first input end IN (P) and the output end OUT may be referred to as an upper arm, and between the second input end IN (N) and the output end OUT may be referred to as a lower arm. In the semiconductor module 2 described above with reference to FIGS. 1 to 3, the switching element 503 and the diode element 504 in the upper arm are formed in the first semiconductor element 5A, and the switching element 505 and the diode element 506 in the lower arm are formed in the second semiconductor element 5B.

In a case where the switching elements 503 and 505 are IGBT elements, the first main electrode on the bottom surface side of the first semiconductor element 5A and the second semiconductor element 5B is referred to as a collector electrode, and the second main electrode on the top surface side is referred to as an emitter electrode. The collector electrode of the switching element 503 of the upper arm is connected to the first input end IN (P) that may be the first input terminal 801, and the emitter electrode of the switching element 505 of the lower arm is connected to the second input end IN (N) that may be the second input terminal 802. The first input end IN (P) and the second input end IN (N) are respectively connected to a positive electrode and a negative electrode of a DC power supply. The emitter electrode of the switching element 503 of the upper arm and the collector electrode of the switching element 505 of the lower arm are connected to the output end OUT that may be the output terminal 803. Furthermore, a gate of the switching element 503 and a gate of the switching element 505 are connected to a control circuit (not illustrated), respectively via the first control terminal 804 and the second control terminal 805.

The half-bridge inverter circuit illustrated in FIG. 4 can convert a direct current between the first input end IN (P) and the second input end IN (N) into an alternating current and output the alternating current from the output end OUT, by a control signal applied to the gate of the switching element 503 of the upper arm and a control signal applied to the gate of the switching element 505 of the lower arm. Furthermore, by connecting the three half-bridge inverter circuits illustrated in FIG. 4 in parallel between the first input end IN (P) and the second input end IN (N) and by controlling the control signal to be applied to each circuit, it is possible to form a three-phase AC inverter circuit.

The semiconductor module 2 including the half-bridge inverter circuit described above with reference to FIG. 4 is not limited to have the configuration described above with reference to FIGS. 1 to 3. The switching elements 503 and 505 may include, for example, a power metal oxide semiconductor field effect transistor (MOSFET), a bipolar junction transistor (BJT), or the like. In a case where the switching element is a MOSFET element, the main electrode on the bottom surface side of the semiconductor elements 5A and 5B may be referred to as a drain electrode, and the main electrode on top surface side may be referred to as a source electrode. Furthermore, the diode elements 504 and 506 may include, for example, a schottky barrier diode (SBD), a junction barrier schottky (JBS) diode, a merged PN schottky (MPS) diode, a PN diode, or the like. Furthermore, a substrate on which the switching elements 503 and 505 and the diode elements 504 and 506 are formed is not limited to a Si substrate, and may be, for example, a substrate using a wide band gap semiconductor such as silicon carbide (SiC) or gallium nitride (GaN).

Furthermore, in the semiconductor module 2, for example, the switching element 503 and the diode element 504 of the upper arm and the switching element 505 and the diode element 506 of the lower arm may be different semiconductor elements. For example, the switching element 503 and the diode element 504 of the upper arm are not limited to the single semiconductor element 5A (single semiconductor chip) in which these are formed on a single semiconductor substrate and may include one or more semiconductor elements (one or more semiconductor chips) on which the switching element 503 is formed and one or more semiconductor elements (one or more semiconductor chips) on which the diode element 504 is formed. The shape, number, placement, and the like of the semiconductor element can be changed as appropriate. A layout of a conductor pattern as the wiring member provided on the top surface side of the wiring board 4 is changed according to the type and shape of the semiconductor element to be mounted, the number of the semiconductor elements to be arranged, the placement of the semiconductor elements, and the like. Furthermore, some or all of the bonding wires 7A to 7F in the semiconductor module 2 described above may be replaced with leads that are formed by processing a metal plate such as a copper plate, for example.

Furthermore, the control electrodes provided on the top surfaces of the semiconductor elements 5A and 5B may include a gate electrode and an auxiliary electrode. For example, the auxiliary electrode may be an auxiliary emitter electrode or an auxiliary source electrode electrically connected to the main electrode on the top surface side and serving as a reference potential with respect to a gate potential. Furthermore, the auxiliary electrode may be a temperature sensing electrode that is electrically connected to a temperature sensing unit that may be included in an inverter device or the like including the semiconductor module 2 and measures temperatures of the semiconductor elements 5A and 5B. These electrodes (main electrode and control electrode including gate electrode and auxiliary electrode) formed on the top surfaces of the semiconductor elements 5A and 5B may be collectively referred to as upper surface electrodes.

A circuit configuration of the semiconductor module 2 is not limited to the half-bridge inverter circuit described above with reference to FIG. 4. The inverter circuit of the semiconductor module 2 may be, for example, a single-phase full-bridge inverter circuit. Furthermore, the inverter circuit in the single semiconductor module 2 is not limited to a single phase and may be, for example, the three-phase AC inverter circuit as described above.

The cooler 10 attached to the semiconductor module 2 described above with reference to FIGS. 1 to 3 includes the fin 11 and the water jacket 12. As illustrated in FIG. 2, the fin 11 includes a base 1101 having the top surface 1110 on which the semiconductor module 2 is attached, and a plurality of fin portions 1102 extending downward from a bottom surface of the base 1101. When being attached to the fin 11, the water jacket 12 has a shape for defining a flow path of a refrigerant in which the fin portion 1102 is arranged. The energy conversion device 1 according to the present embodiment conducts a part of the heat generated by the semiconductor elements 5A and 5B during an operation of the semiconductor module 2 to the cooler 10 via the wiring board 4 and the heat dissipation base 3 and dissipates the heat. In this type of energy conversion device 1, by improving adhesion between the heat dissipation base 3 and the fin 11 with the heat conductive material 14 such as thermal grease, it is possible to efficiently conduct the heat from the heat dissipation base 3 to the cooler 10 (fin 11). Note that, although the cooler 10 is a water jacket integrated type including the water jacket 12, the cooler 10 may be an open-fin-type cooler from which the fin portion 1102 is exposed outside, or the like.

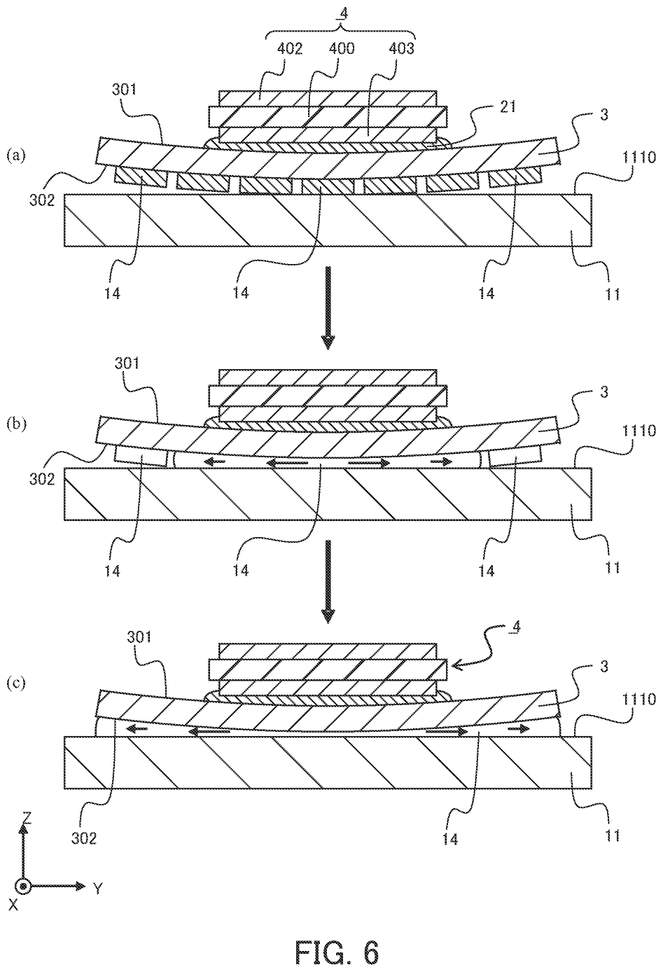

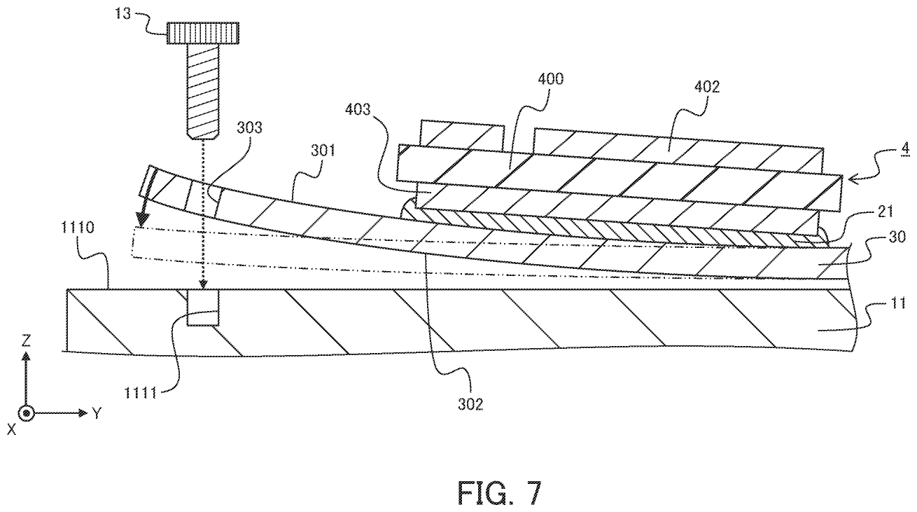

FIG. 5 is a bottom view for explaining an example of a coating pattern of the heat conductive material 14 when the heat dissipation base 3 is attached to the cooler 10. FIG. 6 is a diagram for explaining a state of spread of the heat conductive material 14 when the heat dissipation base 3 is attached to the cooler 10. FIG. 7 is a diagram for explaining an example of a problem that occurs when the heat dissipation base 3 is attached to the cooler 10. Note that, in FIGS. 6 and 7, the fin portion 1102 of the fin 11 is omitted.

In a case where the adhesion between the heat dissipation base 3 and the fin 11 is improved with the heat conductive material 14 such as thermal grease, for example, as illustrated in FIGS. 5 and (a) of 6, the plurality of heat conductive materials 14 is arranged on the bottom surface 302 of the heat dissipation base 3 in a predetermined pattern. The heat dissipation base 3 has a shape in plan view of which the corner portion of the rectangle is rounded, and the fastening hole 303 in which the screw 13 is inserted is formed at the corner portion. Furthermore, for example, the heat dissipation base 3 has a shape in which the flat plate-like metal plate is warped so that the bottom surface 302 has a convex curved surface through press working or the like. The bottom surface 302 of the heat dissipation base 3 illustrated in (a) to (c) of FIG. 6 is a curved surface in which a center portion of the bottom surface 302 becomes a top portion in plan view and a change in a relative position of each point of the bottom surface 302 with respect to the center portion in the Z direction is represented by a downward convex curve.

The plurality of heat conductive materials 14 is arranged on the bottom surface 302 of the heat dissipation base 3, except for a portion around the fastening hole 303. An arrangement pattern of the plurality of heat conductive materials 14 is not limited to a pattern in which same shapes with the same dimensions are aligned and arranged as illustrated in FIG. 5. The plurality of heat conductive materials 14 arranged on the bottom surface 302 of the heat dissipation base 3 may have a plurality of shapes or may have the same shape and a plurality of dimensions, for example. For example, the arrangement pattern of the plurality of heat conductive materials 14 may change in accordance with a distance from the center of the bottom surface 302 of the heat dissipation base 3 in plan view.

When the bottom surface 302 of the heat dissipation base 3 is arranged on the fin 11 to face the top surface 1110 of the fin 11, as illustrated in (a) of FIG. 6, the heat conductive materials 14 arranged at the center of the bottom surface 302 and the vicinity thereof first have contact with the top surface 1110 of the fin 11. Thereafter, for example, when the heat dissipation base 3 is pressed against the top surface 1110 of the fin 11, as illustrated in (b) and (c) of FIG. 6, the heat conductive material 14 having contact with the fin 11 is integrated between the bottom surface 302 of the heat dissipation base 3 and the top surface 1110 of the fin 11 while radially extending from the center of the bottom surface 302. At this time, when the bottom surface 302 of the heat dissipation base 3 is formed to be a convex curved surface, the heat conductive material 14 easily and radially extends from the center of the bottom surface 302 of the heat dissipation base 3, and a gap is hardly generated in the integrated heat conductive material 14.

However, when the heat dissipation base 3 is attached to the fin 11 of the cooler 10, as illustrated in (a) to (c) of FIG. 6, the wiring board 4 is bonded to a top surface 301 of the heat dissipation base 3. Furthermore, when the heat dissipation base 3 is attached to the fin 11 of the cooler 10, after the heat conductive material 14 is extended between the heat dissipation base 3 and the fin 11, and the heat dissipation base 3 is fixed to the fin 11 using the screw 13.

FIG. 7 schematically illustrates deformation of a heat dissipation base 30 that occurs when the heat dissipation base 30 according to a comparative example (configuration in which recesses such as grooves 304 to 306, a cut-away part 307, or the like to be described later are not provided) is attached to the fin 11 of the cooler 10.

In a case where the fastening hole 303 for screwing is positioned at the corner portion of the bottom surface 302 of the heat dissipation base 30, when the screw 13 that is inserted into the fastening hole 303 is screwed into a screw hole 1111 in the top surface 1110 of the fin 11, as illustrated in FIG. 7, the heat dissipation base 30 is deformed from the convex curved surface of the bottom surface 302 (curved surface indicated by solid curved line) to a nearly-flat curved surface with a small curvature (curved surface indicated by alternate long and two short dashed curved line). That is, when the heat dissipation base 30 is attached to the fin 11 with the screw 13, the heat dissipation base 30 is deformed in a direction in which a warpage becomes smaller than that before the attachment. When the deformation of the heat dissipation base 30 occurs in the direction in which the warpage becomes smaller, a deformation stress equal to or more than a deflective strength (for example, ceramic strength of insulating substrate 400) is applied to the wiring board 4 bonded to the top surface 301 of the heat dissipation base 30, and this causes a damage of the wiring board 4, for example, the insulating substrate 400 is cracked or the conductor patterns 401 to 403 are peeled off from the insulating substrate 400. Such a damage of the wiring board 4 easily occurs in a case where an area of the bottom surface 302 of the heat dissipation base 30 is large, the wiring board 4 is arranged to the vicinity of the fastening hole 303, and the fastening hole 303 in which the screw 13 is inserted is formed at the corner portion of the bottom surface 302.

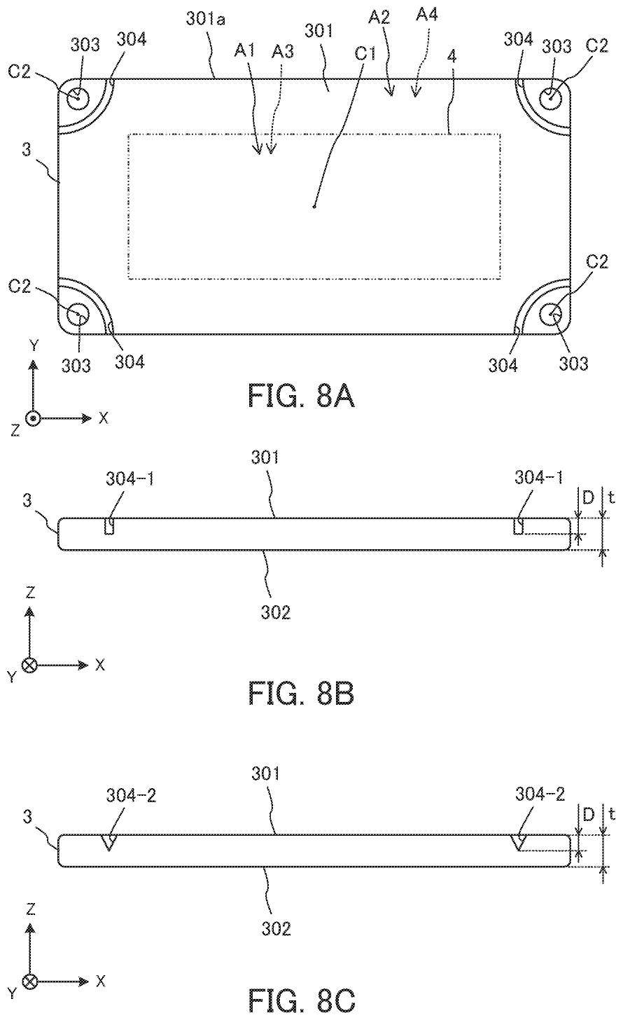

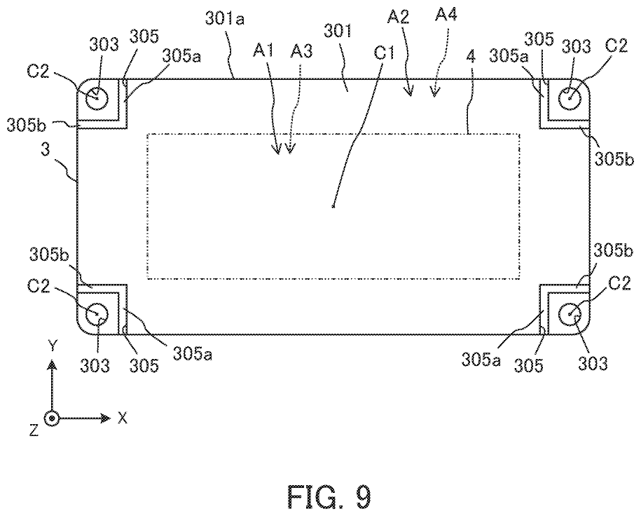

FIG. 8A is a top view illustrating a first configuration example of the heat dissipation base 3 according to the embodiment, and FIGS. 8B and 8C are side views illustrating two examples of a cross-sectional shape of the groove 304. Note that, in FIG. 8A and FIGS. 9, 10A, and 11A to be described later, the wiring board 4 bonded to the top surface 301 of the heat dissipation base 3 is indicated by an alternate long and two short dashed line (imaginary line).

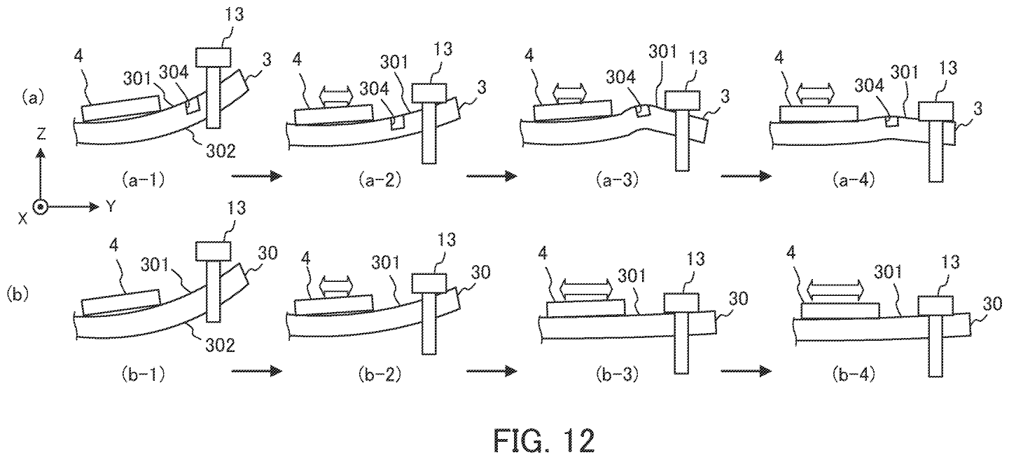

As illustrated in FIG. 8A, the heat dissipation base 3 has the groove 304 (example of recess) positioned around each of the four fastening holes 303, on the top surface 301. The groove 304 is provided across a peripheral edge 301a (any one of four sides of top surface 301) of the top surface 301. Furthermore, the groove 304 is positioned around the fastening hole 303, in a second region A2 excluding a first region A1 bonded to the wiring board 4, of the top surface 301. Here, around the fastening hole 303 is, for example, a region on both fastening hole 303 sides in the XY direction than a center C1 of the top surface 301, and more desirably, may be a region on both fastening hole 303 sides in the XY direction than the first region A1. In the bottom surface 302, a region positioned on an opposite side of the first region A1 of the top surface 301 is a third region A3, and in the bottom surface 302, a region excluding the third region A3 and the fastening hole 303 is a fourth region A4. Since the third region A3 and the fourth region A4 are not illustrated in FIG. 8A, leaders of these are indicated as broken lines. As illustrated in FIGS. 8B and 8C, it is sufficient that the bottom surface 302 (at least, fourth region A4) have a curved shape in which a groove is not provided (curved surface having convex center as exaggeratedly illustrated in FIG. 6). Then, it is preferable that the bottom surface 302 be an extension of the convex curved surface on the opposite side of the groove 304 with respect to the heat dissipation base 3 while overlapping the groove 304 (example of recess) in plan view (refer to (a) of FIG. 12 to be described later). In other words, it is sufficient that a portion of the bottom surface 302 overlapping the groove 304 of the top surface 301 in plan view be an extension of the convex curved surface of the bottom surface 302. As a result, the heat conductive material 14 such as thermal grease described above can be sufficiently spread to the vicinity of the fastening hole 303.

The four grooves 304 positioned around the four fastening holes 303 are provided to surround the fastening holes 303 across the two sides of the peripheral edge 301a orthogonal to each other having the corner portion of the top surface 301 (R chamfered portion) therebetween. As a result, the groove 304 is provided so as to pass through between the fastening hole 303 (or center C2 of fastening hole 303) and the first region A1 (or center C1 in top surface 301) (that is, across region connecting these). The groove 304 extends in an arc shape. For example, the groove 304 extends in an arc shape, concentrically around the side of the fastening hole 303 (or corner portion side of top surface 301).

A cross-sectional shape of the groove 304 (shape orthogonal to extending direction of groove 304) may be a rectangular shape like a rectangular groove 304-1 illustrated in FIG. 8B or may be a V shape like a V groove 304-2 illustrated in FIG. 8C. Alternatively, the cross-sectional shape of the groove 304 can be any shape such as a U shape (U-shaped groove) of which a width is narrowed as approaching to a bottom portion similarly to the V groove 304-2, a T-shape groove of which a width is wider on a bottom portion side, or a dovetail groove. As an example, a depth D of the groove 304 (corner groove 304-1 and V groove 304-2) is equal to or less than a half of a thickness t of the heat dissipation base 3. Any method such as press working can be adopted to form the groove 304.

FIG. 9 is a top view illustrating a second configuration example of the heat dissipation base 3 according to the embodiment.

As illustrated in FIG. 9, the heat dissipation base 3 has a groove 305 (example of recess) positioned around each of the four fastening holes 303, on the top surface 301. The groove 305 is provided across the peripheral edge 301a of the top surface 301. Furthermore, the groove 305 is positioned around the fastening hole 303, in the second region A2 excluding the first region A1 bonded to the wiring board 4, in the top surface 301. Although not illustrated, similarly to the heat dissipation base 3 illustrated in FIGS. 8B and 8C, it is sufficient that the bottom surface 302 (at least, fourth region A4) have a curved shape in which a groove is not provided (curved surface having convex center as exaggeratedly illustrated in FIG. 6).

Each of the four grooves 305 positioned around the four fastening holes 303 includes a first straight portion 305a extending in a direction intersecting with (for example, orthogonal to) a first side of the peripheral edge 301a of the top surface 301 and a second straight portion 305b extending in a direction intersecting with (for example, orthogonal to) a second side orthogonal to the first side of the peripheral edge 301a. That is, the groove 305 is provided to surround the fastening hole 303 across the two sides of the peripheral edge 301a orthogonal to each other, having the corner portion (R chamfered portion) of the top surface 301 therebetween. As a result, the groove 305 is provided so as to pass through between the fastening hole 303 (or center C2 of fastening hole 303) and the first region A1 (or center C1 in top surface 301).

A cross-sectional shape of the groove 305 (shape orthogonal to extending direction of groove 305) can be any shape such as the rectangular groove 304-1 illustrated in FIG. 8B or the V groove 304-2 illustrated in FIG. 8C. As described with respect to the rectangular groove 304-1 and the V groove 304-2 illustrated in FIGS. 8B and 8C, it is sufficient that a depth of the groove 305 be equal to or less than a half of a thickness of the heat dissipation base 3, and any method such as press working can be adopted to form the groove 305.

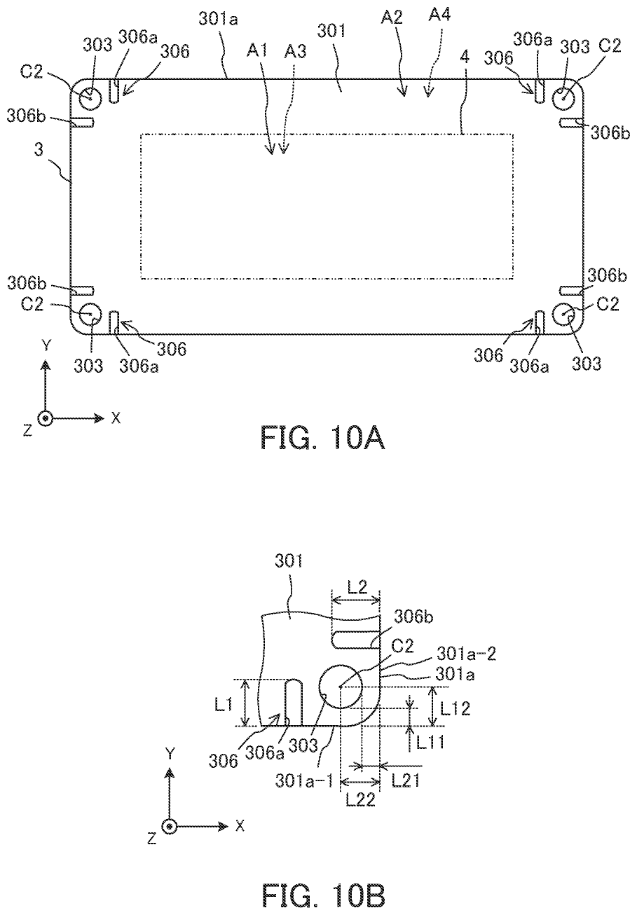

FIG. 10A is a top view illustrating a third configuration example of the heat dissipation base 3 according to the embodiment, and FIG. 10B is a diagram for explaining a length of the groove 306 (first portion 306a and second portion 306b).

As illustrated in FIG. 10A, the heat dissipation base 3 has the groove 306 (example of recess) positioned around each of the four fastening holes 303, on the top surface 301. The groove 306 includes the first portion 306a and the second portion 306b. The first portion 306a and the second portion 306b are provided across the peripheral edge 301a of the top surface 301. Furthermore, the first portion 306a and the second portion 306b are positioned around the fastening hole 303, in the second region A2 excluding the first region A1 bonded to the wiring board 4 in the top surface 301. Although not illustrated, similarly to the heat dissipation base 3 illustrated in FIGS. 8B and 8C, it is sufficient that the bottom surface 302 (at least, fourth region A4) have a curved shape in which a groove is not provided (curved surface having convex center as exaggeratedly illustrated in FIG. 6).

The first portion 306a and the second portion 306b are provided to be separated from each other around the single fastening hole 303. The first portion 306a extends from a first side 301a-1 of the peripheral edge 301a of the top surface 301 (refer to FIG. 10B) in a direction different from the first side 301a-1. Furthermore, the second portion 306b extends from a second side 301a-2 of the peripheral edge 301a (refer to FIG. 10B) in a direction different from the second side 301a-2. Note that, although the first portion 306a and the second portion 306b extend in a straight line in a direction intersecting with the first side 301a-1 or the second side 301a-2, the first portion 306a and the second portion 306b may extend in curved line. Furthermore, one of the first portion 306a and the second portion 306b may be omitted. That is, the groove 306 may be a groove including a single portion, of which only one end is provided across the peripheral edge 301a of the top surface 301, around the fastening hole 303. In this case, the groove including the single portion may extend in a straight line or extend in an arc shape.

As illustrated in FIG. 10B, it is sufficient that the first portion 306a extend to be longer than a length L11 from the first side 301a-1 to the fastening hole 303 (length L1>L11) and extend on the top surface 301 from the first side 301a-1. Furthermore, the first portion 306a may extend to be longer than a length L12 from the first side 301a-1 to the center C2 of the fastening hole 303 (length L1>L12) and extend on the top surface 301 from the first side 301a-1.

It is sufficient that the second portion 306b extend to be longer than a length L21 from the second side 301a-2 to the fastening hole 303 (length L2>L21) and extend on the top surface 301 from the second side 301a-2. Furthermore, the second portion 306b may extend to be longer than a length L22 from the second side 301a-2 to the center C2 of the fastening hole 303 (length L2>L22) and extend on the top surface 301 from the second side 301a-2.

A cross-sectional shape of the groove 306 (shape orthogonal to extending direction of groove 306) can be any shape such as the rectangular groove 304-1 illustrated in FIG. 8B or the V groove 304-2 illustrated in FIG. 8C. As described with respect to the groove 304 illustrated in FIGS. 8A to 8C, it is sufficient that the depth of the groove 306 be equal to or less than the half of the thickness of the heat dissipation base 3, and any method such as press working can be adopted to form the groove 306.

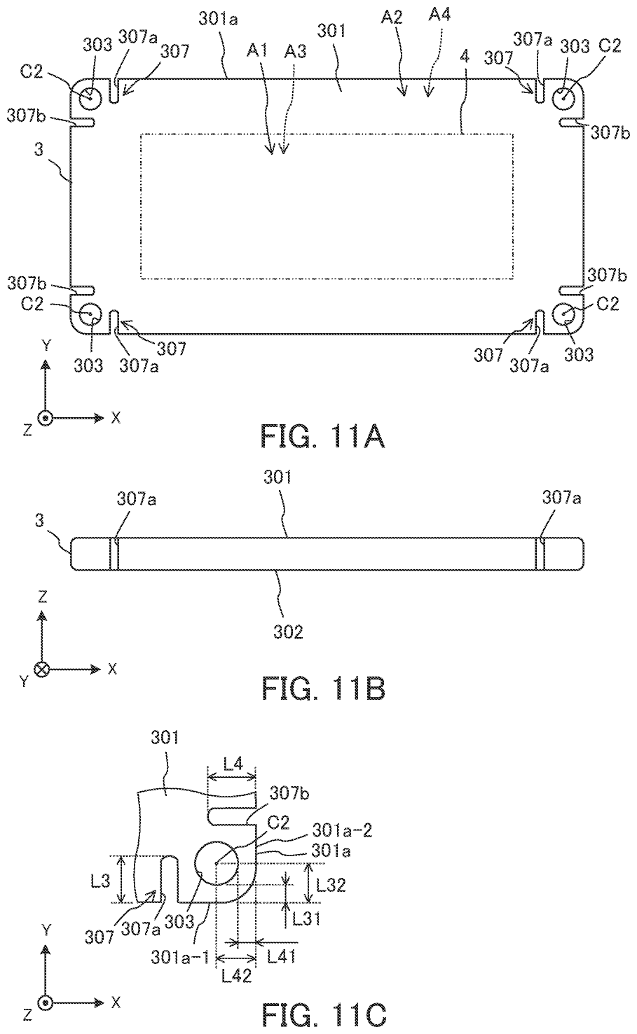

FIG. 11A is a top view illustrating a fourth configuration example of the heat dissipation base 3 according to the embodiment, FIG. 11B is a side view, and FIG. 11C is a diagram for explaining a length of the cut-away part 307.

As illustrated in FIG. 11A, the heat dissipation base 3 has the cut-away part 307 (example of recess) including a first portion 307a and a second portion 307b positioned around each of the four fastening holes 303, on the top surface 301. The first portion 307a and the second portion 307b are provided across the peripheral edge 301a of the top surface 301 and pass through the heat dissipation base 3 in a thickness direction (Z direction) as illustrated in FIG. 11B. Furthermore, the first portion 307a and the second portion 307b are positioned around the fastening hole 303, in the second region A2 excluding the first region A1 bonded to the wiring board 4 in the top surface 301. Cross-sectional shapes (shape orthogonal to extending directions of first portion 307a and second portion 307b) of the first portion 307a and the second portion 307b have a constant width across the thickness direction of the heat dissipation base 3, for example. However, the width does not need to be constant, for example, the width on the top surface 301 side may be wider than that on the bottom surface 302 side. The bottom surface 302 (at least fourth region A4) illustrated in FIG. 11B may have a curved shape (curved surface having convex center exaggeratedly illustrated in FIG. 6).

The first portion 307a and the second portion 307b are provided to be separated from each other around the single fastening hole 303. The first portion 307a extends from the first side 301a-1 of the peripheral edge 301a of the top surface 301 (refer to FIG. 11C) in a direction different from the first side 301a-1 (for example, orthogonal direction). Furthermore, the second portion 307b extends from the second side 301a-2 (refer to FIG. 11C) of the peripheral edge 301a in a direction different from the second side 301a-2 (for example, orthogonal direction). Note that, the first portion 307a and the second portion 307b may extend in a straight line in a direction intersecting with the first side 301a-1 or the second side 301a-2 or may extend in a curved line. Furthermore, one of the first portion 307a and the second portion 307b may be omitted. That is, the cut-away part 307 may be a cut including a single portion, of which only one end is provided along the peripheral edge 301a of the top surface 301, around the fastening hole 303. In this case, the cut-away part including the single portion may extend in a straight line or extend in an arc shape. Any method such as press working can be adopted to form the cut-away part 307.

It is sufficient that the first portion 307a extend to be longer than a length L31 from the first side 301a-1 to the fastening hole 303 (length L3>L31) and extend on the top surface 301 from the first side 301a-1. Furthermore, the first portion 307a may extend to be longer than a length L32 from the first side 301a-1 to the center C2 of the fastening hole 303 (length L3>L32) and extend on the top surface 301 from the first side 301a-1.

It is sufficient that the second portion 307b extend to be longer than a length L41 from the second side 301a-2 to the fastening hole 303 (length L4>L41) and extend on the top surface 301 from the second side 301a-2. Furthermore, the second portion 307b may extend to be longer than a length L42 from the second side 301a-2 to the center C2 of the fastening hole 303 (length L4>L42) and extend on the top surface 301 from the second side 301a-2.

Note that a length of the cut-away part 307 (length L3 of first portion 307a and length L4 of second portion 307b) illustrated in FIG. 11C is, for example, the same as a length of the groove 306 (length L1 of first portion 306a and length L2 of second portion 306b) illustrated in FIG. 10B described above. However, since the cut-away part 307 passes through the heat dissipation base 3 in the thickness direction, in order to prevent a crack of the heat dissipation base 3 or the like due to the formation of the cut-away part 307, the cut-away part 307 may be provided to be shorter than that in a case where the groove 306 is provided.

FIG. 12 is a diagram for explaining a difference in tensile stresses to be applied to the wiring board 4 between the present embodiment ((a) of FIG. 12) and the comparative example ((b) of FIG. 12). Note that (a) ((a-1) to (a-4)) of FIG. 12 illustrate the heat dissipation base 3 according to the present embodiment having the groove 304 as an example of the recess, and (b) ((b-1) to (b-4)) of FIG. 12 illustrate the heat dissipation base 30 according to the comparative example in which the recess (grooves 304 to 306, cut-away part 307, or the like) is not provided.

As exaggeratedly illustrated in (a-1) and (b-1) of FIG. 12, the bottom surface 302 of the heat dissipation bases 3 and 30 is warped to have a convex curved surface, as described above.

As illustrated in (a-2) and (b-2) of FIG. 12, in a process for fastening the heat dissipation bases 3 and 30 to the cooler (not illustrated) (refer to cooler 10 illustrated in FIG. 3) with the screw 13, the heat dissipation bases 3 and 30 are pressed downward by the screw 13 and are deformed so that the warpage of the bottom surface 302 is reduced. At this time, tensile stresses indicated by double-headed arrows are applied to the wiring board 4

As illustrated in (a-3) and (b-3) of FIG. 12, as the screw 13 is fastened, in (b-3) of FIG. 12 of the comparative example, in a process in which the warpage of the bottom surface 302 is almost eliminated by local deformation near the fastening hole 303, the tensile stress applied to the wiring board 4 gradually increases. On the other hand, in (a-3) of FIG. 12 of the present embodiment, the deformation of the heat dissipation base 3 on the side of the screw 13 is less likely to be transmitted to the wiring board 4 side with the groove 304 as a fulcrum, and the tensile stress applied to the wiring board 4 is less likely to increase. The tensile stress applied to the wiring board 4 is less likely to increase in this way not only in a case where the groove 304 is provided in the heat dissipation base 3 but also in a case where the grooves 305 and 306 and the cut-away part 307 described above are provided.

As a result, while the top surface 301 approaches a planar shape after fastening the screw 13 in (b-4) of FIG. 12, there is a case where the top surface 301 has a convex shape near the groove 304 in (a-4) of FIG. 12. However, since the groove 304 in the present embodiment is provided in a region (refer to second region A2) different from the region to which the wiring board 4 is bonded (refer to first region A1 in FIG. 8A), heat dissipation property of the semiconductor module 2 (compound wettability of heat conductive material 14 or the like illustrated in FIG. 3) is less likely to be adversely affected.

The semiconductor module 2 according to the present embodiment described above includes the semiconductor elements 5A and 5B, the wiring board 4 on which the semiconductor elements 5A and 5B are mounted, and the heat dissipation base 3. Furthermore, the heat dissipation base 3 according to the present embodiment includes the top surface (example of first surface) 301 to which the wiring board 4 is bonded and the bottom surface (example of second surface) 302 positioned on the opposite side of the top surface. Furthermore, the bottom surface 302 of the heat dissipation base 3 is warped to be a convex curved surface. The fastening holes 303 are provided at the plurality of corner portions on the top surface 301 of the heat dissipation base 3. Then, in the second region A2 excluding the first region A1, bonded to the wiring board 4, in the top surface 301, the heat dissipation base 3 has the recess (for example, grooves 304 to 306 and cut-away part 307) positioned around the fastening hole 303 and across the peripheral edge 301a of the top surface 301.

As a result, when the heat dissipation base 3 is fastened to the cooler 10 on the bottom surface 302 that is the convex curved surface, even if the heat dissipation base 3 is deformed so as to reduce the warpage of the bottom surface 302, the deformation of the heat dissipation base 3 on the side of the fastening hole 303 (screw 13) is less likely to be transmitted to the wiring board 4 side, with the recess as a fulcrum. Furthermore, the tensile stress applied to the wiring board 4 is less likely to increase. Therefore, according to the present embodiment, the damage of the wiring board 4 due to the deformation of the heat dissipation base 3 at the time of fastening can be prevented.

Furthermore, in the present embodiment, the recess provided across the peripheral edge 301a of the top surface 301 includes the grooves 304 to 306 provided in the top surface 301.

As a result, as compared with a case where the cut-away part 307 is provided in the heat dissipation base 3, a degree of freedom of formation positions of the grooves 304 to 306 is increased, for example, by making the grooves 304 to 306 to have shapes surrounding the fastening holes 303. Furthermore, the damage of the wiring board 4 due to the deformation of the heat dissipation base 3 at the time of fastening can be prevented.

Furthermore, in the present embodiment, the fourth region A4 excluding the third region A3 positioned on the opposite side of the first region A1 and the fastening hole 303, in the bottom surface 302 has a curved shape in which no groove is provided.

As a result, with simple processing for providing the grooves 304 to 306 only in the top surface 301 of the heat dissipation base 3 and without hindering the heat conduction from the bottom surface 302 of the heat dissipation base 3 to the cooler 10, the damage of the wiring board 4 due to the deformation of the heat dissipation base 3 at the time of fastening can be prevented.

Furthermore, in the present embodiment, the grooves 304 and 305 are provided so as to pass through between the fastening hole 303 and the first region A1.

As a result, with the grooves 304 and 305 positioned between the fastening hole 303 and the first region A1 (wiring board 4), the deformation of the heat dissipation base 3 on the side of the fastening hole 303 (screw 13) can be less likely to be transmitted to the side of the wiring board 4. Therefore, the damage of the wiring board 4 due to the deformation of the heat dissipation base 3 at the time of fastening can be further prevented.

Furthermore, in the present embodiment, the grooves 304 and 305 are provided so as to surround the fastening hole 303 across the orthogonal two sides of the peripheral edge 301a of the top surface 301 having the corner portion of the top surface 301 therebetween.

As a result, the deformation of the heat dissipation base 3 on the side of the fastening hole 303 (screw 13) can be further hardly be transmitted to the side of the wiring board 4. Therefore, the damage of the wiring board 4 due to the deformation of the heat dissipation base 3 at the time of fastening can be reliably prevented.

Furthermore, in the present embodiment, the groove 304 provided so as to surround the fastening hole 303 across the two sides of the peripheral edge 301a of the top surface 301 extends in an arc shape.

As a result, with simple processing for providing the single curved groove 304, the damage of the wiring board 4 due to the deformation of the heat dissipation base 3 at the time of fastening can be prevented.

Furthermore, in the present embodiment, the groove 305 provided so as to surround the fastening hole 303 across the two sides of the peripheral edge 301a of the top surface 301 includes the first straight portion 305a extending in the direction intersecting with the first side of the peripheral edge 301a of the top surface 301 and the second straight portion 305b extending in the direction intersecting with the second side orthogonal to the first side of the peripheral edge 301a.

As a result, with simple processing for providing the single straight groove 305, the damage of the wiring board 4 due to the deformation of the heat dissipation base 3 at the time of fastening can be prevented.

Furthermore, in the present embodiment, the recess provided across the peripheral edge 301a of the top surface 301 is the cut-away part 307 that is provided at the peripheral edge 301a of the top surface 301 of the heat dissipation base 3 and passes through the heat dissipation base 3 in the thickness direction (Z direction).

As a result, with the cut-away part 307 across the entire heat dissipation base 3 in the thickness direction, the deformation of the heat dissipation base 3 in which the warpage of the bottom surface 302 is reduced at the time when the heat dissipation base 3 is fastened to the cooler 10 is less likely to be transmitted to the side of the wiring board 4 than a case where the grooves 304 to 306 are provided. Therefore, the damage of the wiring board 4 due to the deformation of the heat dissipation base 3 at the time of fastening can be further prevented. Furthermore, the cut-away part 307 can be more easily processed than a case where the grooves 304 to 306 are provided.

Furthermore, in the present embodiment, the recess (for example, groove 306 and cut-away part 307) provided across the peripheral edge 301a of the top surface 301 includes the first portions 306a and 307a and the second portions 306b and 307b provided to be separated from each other around the single fastening hole 303. The first portions 306a and 307a extend from the first side 301a-1 of the peripheral edge 301a of the top surface 301 in the direction different from the first side 301a-1, and the second portions 306b and 307b extend from the second side 301a-2 orthogonal to the first side 301a-1 of the peripheral edge 301a in the direction different from the second side 301a-2.

As a result, as compared with a case where the recess extends from one side of the peripheral edge 301a of the top surface 301 in parallel to this side, the deformation of the heat dissipation base 3 in which the warpage of the bottom surface 302 is reduced at the time when the heat dissipation base 3 is fastened to the cooler 10 can be less likely to be transmitted to the side of the wiring board 4. Furthermore, the deformation of the heat dissipation base 3 can be less likely to be transmitted to the side of the wiring board 4 than a case where a single portion (for example, one of first portions 306a and 307a and second portions 306b and 307b) is provided as the recess.

Furthermore, in the present embodiment, as illustrated in FIG. 10B and FIG. 11C, the first portions 306a and 307a extend to be longer than the lengths L11 and L31 from the first side 301a-1 to the single fastening hole 303 (L1>L11, L3>L31) and extend on the top surface 301 from the first side 301a-1. Furthermore, the second portions 306b and 307b extend to be longer than the lengths L21 and L41 from the second side 301a-2 to the single fastening hole 303 (L2>L21, L4>L41) and extend from the second side 301a-2 on the top surface 301.

As a result, as compared with a case where the lengths of the first portions 306a and 307a and the second portions 306b and 307b are shorter, the deformation of the heat dissipation base 3 can be less likely to be transmitted to the side of the wiring board 4.

Furthermore, in the present embodiment, the first portions 306a and 307a extend to be longer than the lengths L12 and L32 from the first side 301a-1 to the center C2 of the single fastening hole 303 (L1>L12, L3>L32) and extend on the top surface 301 from the first side 301a-1. Furthermore, the second portions 306b and 307b extend to be longer than the lengths L22 and L42 from the second side 301a-2 to the center C2 of the single fastening hole 303 (L2>L22, L4>L42) and extend on the top surface 301 from the second side 301a-2.

As a result, as compared with a case where the lengths of the first portions 306a and 307a and the second portions 306b and 307b are shorter, the deformation of the heat dissipation base 3 can be less likely to be transmitted to the side of the wiring board 4.

The embodiments of the semiconductor module 2 and the heat dissipation base 3 according to the present invention are not limited to the above embodiments, and may be variously modified, replaced, and deformed without departing from the spirit of the technical idea. When the technical idea can be achieved in another manner by the progress of the technology or another derived technology, the technical idea may be carried out by using the manner. Therefore, the claims cover all embodiments that may be included within the scope of the technical idea.

For example, in the heat dissipation base 3 according to the above embodiment, a flat-plate-like base plate is warped by press working or the like to make the bottom surface 302 warp to be the convex curved surface, and the top surface 301 to which the wiring board 4 is bonded is warped to be a recessed curved surface. However, the shape of the heat dissipation base 3 according to the present invention is not limited to such a shape. In the heat dissipation base 3 according to the present invention, for example, the bottom surface 302 facing the fin 11 of the cooler 10 may be the convex curved surface, and the top surface 301 to which the wiring board 4 is bonded may be a flat surface. Furthermore, a position of the top when the bottom surface 302 of the heat dissipation base 3 is the convex curved surface is not limited to be the center of the bottom surface 302 in plan view and may be a position separated from the center. Furthermore, the number of wiring boards 4 bonded to the single heat dissipation base 3 may be two or more. In addition, although the recess (grooves 304 to 306, cut-away part 307, or the like) is provided in the second region A2 excluding the first region A1 bonded to the wiring board 4, in the top surface 301 of the heat dissipation base 3, a part of the recess may be provided across the first region A1. Furthermore, the arrangement position and the shape of the recess can be arbitrarily changed, and for example, the plurality of recesses may be provided between the fastening hole 303 of the heat dissipation base 3 and the first region A1 (region to which wiring board 4 is bonded). Furthermore, the recess may be the grooves 304 to 306 and the cut-away part 307 that are continuously provided. Furthermore, for example, the recess is provided to overlap a portion where the corner portion on the outer peripheral side of the insulating member 800 of the case 8 is cut as illustrated in FIG. 1. However, the recess may be provided to overlap the insulating member 800. Moreover, the fastening hole 303 for fastening a screw of the heat dissipation base 3 may be formed, for example, in an intermediate portion of an end in the longitudinal direction, in addition to the corner portion on the bottom surface 302. Furthermore, the shape of the heat dissipation base 3 in plan view is not limited to a substantially rectangular planar shape of which a length of a side extending in the X direction is different from a length of a side extending in the Y direction, as described above with reference to FIG. 8A or the like and may be a substantially square planar shape of which a length of a side extending in the X direction and a length of a side extending in the Y direction are substantially the same.

Hereinafter, some inventions described herein and the drawings are described.

### <Supplementary Note 1>

A semiconductor module including:
a semiconductor element;
a wiring board on which the semiconductor element is mounted; and
a heat dissipation base including a first surface to which the wiring board is bonded and a second surface positioned on an opposite side of the first surface, in which
the heat dissipation base is warped so that the second surface is a convex curved surface,
fastening holes are provided at a plurality of corner portions of the first surface of the heat dissipation base, and
the heat dissipation base has a recess positioned around the fastening hole and across a peripheral edge of the first surface, in a second region excluding a first region, to which the wiring board is bonded, in the first surface.

### <Supplementary Note 2>

The semiconductor module according to supplementary note 1, in which
the recess is a groove provided in the first surface.

### <Supplementary Note 3>

The semiconductor module according to supplementary note 2, in which
in the second surface, a fourth region excluding a third region positioned on an opposite side of the first region and the fastening hole has a curved shape in which a groove is not provided.

### <Supplementary Note 4>

The semiconductor module according to supplementary note 2 or 3, in which
the groove is provided so as to pass through between the fastening hole and the first region.

### <Supplementary Note 5>

The semiconductor module according to supplementary note 4, in which
the groove is provided so as to surround the fastening hole across orthogonal two sides of the peripheral edge of the first surface with the corner portion therebetween.

### <Supplementary Note 6>

The semiconductor module according to supplementary note 5, in which
the groove extends in an arc shape.

### <Supplementary Note 7>

The semiconductor module according to supplementary note 5, in which
the groove includes a first straight portion that extends in a direction intersecting with a first side of the peripheral edge of the first surface and a second straight portion that extends in a direction intersecting with a second side orthogonal to the first side of the peripheral edge of the first surface.

### <Supplementary Note 8>

The semiconductor module according to supplementary note 1, in which
the recess is a cut-away part that is provided at the peripheral edge of the first surface of the heat dissipation base and passes through the heat dissipation base in a thickness direction.

### <Supplementary Note 9>

The semiconductor module according to supplementary note 1 or 8, in which
the recess includes a first portion and a second portion that are provided to be separated from each other around the single fastening hole,
the first portion extends from a first side of the peripheral edge of the first surface in a direction different from the first side, and
the second portion extends from a second side of the peripheral edge of the first surface in a direction different from the second side.

### <Supplementary Note 10>

The semiconductor module according to supplementary note 9, in which
the first portion extends to be longer than a length from the first side to the single fastening hole, on the first surface from the first side, and
the second portion extends to be longer than a length from the second side to the single fastening hole, on the first surface from the second side.

### <Supplementary Note 11>

The semiconductor module according to supplementary note 10, in which
the first portion extends to be longer than a length from the first side to a center of the single fastening hole, on the first surface from the first side, and
the second portion extends to be longer than a length from the second side to the center of the single fastening hole, on the first surface from the second side.

### <Supplementary Note 12>

The semiconductor module according to supplementary note 1, in which
the second surface overlaps the recess in plan view and is an extension of the convex curved surface on an opposite side of the recess with respect to the heat dissipation base.

### <Supplementary Note 13>

A heat dissipation base including a first surface to which a wiring board on which a semiconductor element is mounted is bonded and a second surface positioned on an opposite side of the first surface, in which
the second surface is warped to be a convex curved surface,
fastening holes are provided at a plurality of corner portions of the first surface, and
in a second region different from a first region bonded to the wiring board in the first surface, a recess is included that is positioned around the fastening hole and is provided across a peripheral edge of the first surface.

As described above, the present invention has an effect of preventing a wiring board from being damaged due to deformation of a heat dissipation base at the time of fastening when the heat dissipation base to which the wiring board is bonded is attached to a cooler, and in particular, is useful for an industrial or electrical inverter device.

What is claimed is:

1. A semiconductor module, comprising:
a semiconductor element;
a wiring board on which the semiconductor element is mounted; and
a heat dissipation base including a first surface having a first region in which the wiring board is bonded and a second surface opposite to the first surface, wherein
the heat dissipation base is warped to be convexed in a direction from the first surface toward the second surface,
the heat dissipation base has
a plurality of fastening holes respectively provided at respective ones of a plurality of corner portions of the heat dissipation base, and
a plurality of recesses provided in the first surface in respective ones of a plurality of peripheral areas, the plurality of peripheral areas being respectively located in a second region excluding the first region, at a peripheral edge of the first surface around respective ones of the plurality of fastening holes.

2. The semiconductor module according to claim 1, wherein
each of the plurality of recesses is a groove provided in the first surface.

3. The semiconductor module according to claim 2, wherein
the second surface of the heat dissipation base has a third region positioned directly opposite to the first region of the first surface and a fourth region positioned directly opposite to the second region of the first surface, the third region and the fourth region excluding the plurality of fastening holes forming a curved surface that is free of any groove.

4. The semiconductor module according to claim 2, wherein
the groove is provided so as to pass through an area between one of the plurality of fastening holes and the first region.

5. The semiconductor module according to claim 4, wherein
the heat dissipation base has a rectangular shape in a plan view of the semiconductor module with four corners each formed by two sides orthogonal to each other,
the plurality of fastening holes are respectively provided at respective ones of four corners of the heat dissipation base,
each groove provided at one of the four corners formed by corresponding two sides in the first surface extends from the corresponding two sides.

6. The semiconductor module according to claim 5, wherein
each groove provided at the one of the four corners formed by the corresponding two sides continuously extends from one side of the corresponding two sides to the other side of the corresponding two sides to form an arc shape.

7. The semiconductor module according to claim 5, wherein
each groove provided at the one of the four corners formed by the corresponding two sides includes a first straight portion that extends from one side of the corresponding two sides in a direction orthogonal to the one side and a second straight portion that extends from the other side of the corresponding two sides in a direction orthogonal to the other side.

8. The semiconductor module according to claim 1, wherein
each the plurality of recesses is a cut-away passing through the heat dissipation base from the first surface to the second surface in a thickness direction.

9. The semiconductor module according to claim 1, wherein
the heat dissipation base has a rectangular shape in a plan view of the semiconductor module with four corners each formed by two sides orthogonal to each other,
each of the plurality of recesses at one of four corners formed by corresponding two sides includes a first portion and a second portion that are apart from each other,
the first portion extends from one side of the corresponding two sides in a first direction different from the one side, and
the second portion extends from the other side of the corresponding two sides in a second direction different from the other side.

10. The semiconductor module according to claim 9, wherein
the first portion extends from the one side to have a length longer than a length from the one side to an edge of a corresponding one of the plurality of fastening holes in the first direction, and
the second portion extends from the other side to have a length longer than a length from the other side to an edge of the corresponding one of the plurality of fastening holes in the second direction.

11. The semiconductor module according to claim 10, wherein
the first portion extends to have a length longer than a length from the one side to a center of the corresponding one of the plurality of fastening holes, and
the second portion extends to have a length longer than a length from the other side to the center of the corresponding one of the plurality of fastening holes.

12. The semiconductor module according to claim 1, wherein
the second surface including an area directly opposite to an area where the recess is provided in the first surface forms a carved surface.

13. A heat dissipation base, comprising
a first surface having a first region to which a wiring board having a semiconductor element mounted thereon to be bonded;
a second surface opposite to the first surface; and
a plurality of fastening holes respectively provided at respective ones of a plurality of corners of the heat dissipation base,
a plurality of recesses provided in the first surface in respective ones of a plurality of peripheral areas, each of the plurality of peripheral areas being located in a second region excluding the first region, at a peripheral edge of the first surface around respective ones of the plurality of fastening holes, wherein
the second surface is capable of being warped to be convexed in a direction from the first surface toward the second surface.
